(19) United States
(12) Patent Application Publication
(10) Pub. No.: US 2005/0232034 A1
(43) Pub. Date: Oct. 20, 2005

(54) Auxiliary device for operating M-DOC series flash memory and non-X86 system processor in synchronism

(75) Inventors: Show-Nan Chung, Taipei City (TW); Yi-Tyng Lin, Taipei City (TW); Chin-Peng Tsai, Taipei City (TW)

Correspondence Address: BACON & THOMAS, PLLC, 625 SLATERS LANE, FOURTH FLOOR, ALEXANDRIA, VA, 22314, US

(73) Assignee: Tatung Co., Ltd., Taipei City (TW)

(21) Appl. No.: 10/826,358

(22) Filed: Apr. 19, 2004

(51) Int. Cl. G11C 11/34

(52) U.S. Cl. 365/194

(57) ABSTRACT

An auxiliary device for operating both M-DOC series flash memory and non-X86 system processor in synchronism is provided. The auxiliary device comprises a first logic circuit enabled by a first address line of the non-X86 system processor for changing output thereof from a first level to a second level, a delay circuit for delaying the second level output of the first logic circuit a predetermined period of time prior to clearing the first logic circuit for changing output thereof from a second level to a first level, and a second logic circuit for performing a logical operation on the output of the first logic circuit and a CS pin of the non-X86 system processor prior to coupling to a CS pin of the M-DOC series flash memory. The M-DOC series flash memory thus can be used as both a power on memory and a typical memory.

### BACKGROUND OF THE INVENTION

1. Field of the Invention

The present invention relates to auxiliary devices and, more particularly, to an auxiliary device for operating M-DOC (Disk-On-Chip Millennium) series flash memory and non-X86 system processor in synchronism.

2. Description of Related Art

Flash memory devices produced by M-System Company, Ltd. are widely employed in various embedded systems, telecommunications and the Internet. Among these products, M-DOC series flash memory is widely employed in portable information devices. Conventionally, CPUs (central processing units) of such portable information devices are non-X86 system processors (e.g., Intel CPU SA1110). A timing diagram of the Intel CPU SA1110 and M-DOC series flash memory is shown in FIG. 1. In a time period between t1 and t3 both OE (output enable) pin and CS (chip select) pin of the CPU are enabled. A1 to A25 are address buses of the CPU. In a time period between t1 and t2, CPU reads data. Data read in a time period between t2 and t3 by CPU depends on the change of A0 signal since 1CS0 is at a low level. M-DOC series flash memory is thus unable to act as a power on memory because M-DOC series flash memory does not work in synchronism with non-X86 system processor. Hence, a need for improvement exists.

### SUMMARY OF THE INVENTION

An object of the present invention is to provide an auxiliary device for operating M-DOC series flash memory and non-X86 system processor in synchronism so that M-DOC series flash memory can be used as both a power on memory and a typical memory.

To achieve the above and other objects, the present invention provides an auxiliary device for operating both an M-DOC series flash memory and a non-X86 system processor in synchronism, comprising a first logic circuit enabled by a first address line of the non-X86 system processor for changing output thereof from a first level to a second level; a delay circuit for delaying the second level output of the first logic circuit a predetermined period of time prior to clearing the first logic circuit for changing output thereof from a second level to a first level; and a second logic circuit for performing a logical operation on the output of the first logic circuit and a CS pin of the non-X86 system processor prior to coupling to a CS pin of the M-DOC series flash memory.

Other objects, advantages, and novel features of the present invention will become more apparent from the detailed description when taken in conjunction with the accompanying drawings.

### BRIEF DESCRIPTION OF THE DRAWINGS

FIG. 1 is a timing diagram of conventional M-DOC series flash memory and non-X86 system processor;

FIG. 2 is a circuit diagram of an auxiliary device according to the present invention;

FIG. 3 schematically depicts the connections of the auxiliary device according to the present invention; and

FIG. 4 is a timing diagram of the auxiliary device operated in synchronism with both the M-DOC series flash memory and the non-X86 system processor according to the present invention.

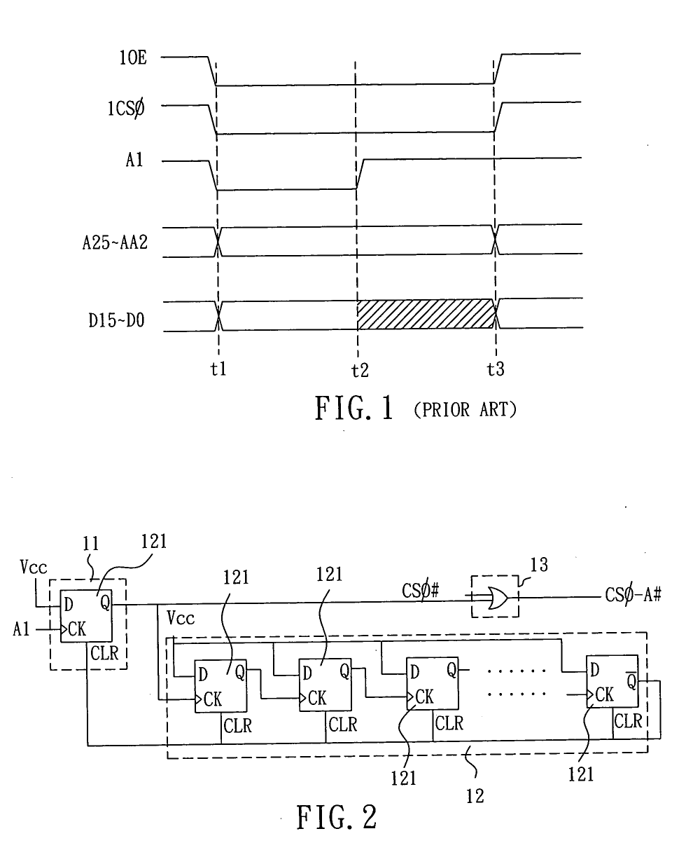

### DETAILED DESCRIPTION OF THE PREFERRED EMBODIMENT

With reference to FIG. 2, there is shown an auxiliary device for operating both M-DOC series flash memory and non-X86 system processor in synchronism in accordance with the present invention. The auxiliary device comprises a first logic circuit 11, a delay circuit 12, and a second logic circuit 13. Each component will be described in detail below. An input of the first logic circuit 11 is a first address line of the non-X86 system processor and an output thereof is coupled to inputs of the delay circuit 12 and the second logic circuit 13 respectively. An inverted output of the delay circuit 12 is coupled to the first logic circuit 11 and a CLR (clear) pin itself respectively. Another input of the second logic circuit 13 is coupled to a CS pin of the non-X86 system processor. An output of the second logic circuit 13 is coupled to a CS pin of the M-DOC series flash memory.

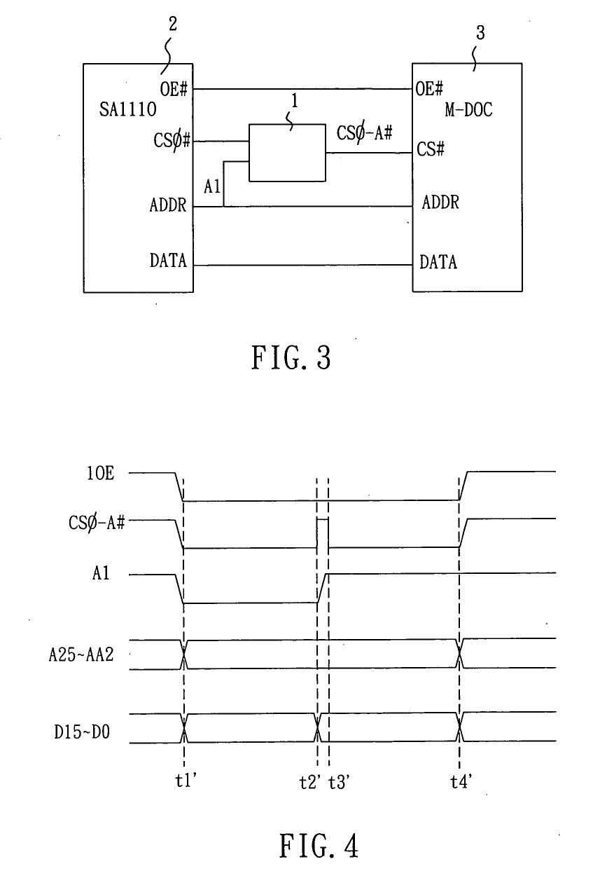

With reference to FIG. 3, there is shown the connections of the auxiliary device. The first logic circuit 11 is implemented as a D flip-flop (D-FF) 121 and is conducted by a first address line of the Intel CPU SA1110 labeled by reference numeral 2. Such conduction is positive edge trigger. That is, the D-FF 121 is conducted to generate a high level output when the first address line changes from a low level to a high level. The delay circuit 12 comprises a plurality D-FFs 121 each also being conducted by positive edge trigger. That is, a next second D-FF 121 is conducted by the first D-FF 121 when an input of the first D-FF 121 changes from a low level to a high level. In such a manner, an inverted output is generated by the last D-FF 121 with both the first logic circuit 11 and the delay circuit 12 cleared and an output of the first logic circuit 11 changed to a low level. As an end, the high level output of the first logic circuit 11 is delayed a predetermined period of time. The second logic circuit 13 is implemented as a logical OR gate 131. An input of the logical OR gate 131 is coupled to a CS pin of the Intel CPU SA 110 and an output of the first logic circuit 11 respectively. The logical OR gate 131 generates a high level output by performing a logical operation when an output of the first logic circuit 11 is at a high level. The high level output is then sent a CS pin of the M-DOC series flash memory.

With reference to FIG. 4, a timing diagram of the auxiliary device is shown. In time point t1′, a CS pin and an OE pin of the Intel CPU SA1110 are low levels and a first address line thereof is also a low level. In a time period between t1′ and t2′, data on a data bus is read. In a time point t2′, the first logic circuit 11 is conducted to generate a high level output when the first address line changes from a low level to a high level. Next, the second logic circuit 13 generates a high level output by performing a logical operation. Also, a high level output of the first logic circuit 11 conducts the delay circuit 12. This delays the D-FFs 121 a predetermined period of time prior to clearing both the first logic circuit 11 and the delay circuit 12 for changing output of the delay circuit 12 from a high level to a low level. This is done in a time period between t2′ and t3′. In a time point t3′, a CS pin of the M-DOC series flash memory is enabled. As such, data can be continuously read until a time point t4′ is reached.

In brief, the auxiliary device for operating both M-DOC series flash memory and non-X86 system processor in synchronism is embodied by means of the first logic circuit 11, the delay circuit 12, and the second logic circuit 13 according to the present invention. Moreover, M-DOC series flash memory thus can be used as both a power on memory and a typical memory.

Although the present invention has been explained in relation to its preferred embodiment, it is to be understood that many other possible modifications and variations can be made without departing from the spirit and scope of the present invention as hereinafter claimed.

1. An auxiliary device for operating both an M-DOC series flash memory and a non-X86 system processor in synchronism, comprising:
a first logic circuit enabled by a first address line of the non-X86 system processor for changing output thereof from a first level to a second level;
a delay circuit for delaying the second level output of the first logic circuit a predetermined period of time prior to clearing the first logic circuit for changing output thereof from a second level to a first level; and
a second logic circuit for performing a logical operation on the output of the first logic circuit and a CS pin of the non-X86 system processor prior to coupling to a CS pin of the M-DOC series flash memory.

2. The auxiliary device as claimed in claim 1, wherein the delay circuit comprises a plurality flip-flops (FFs).

3. The auxiliary device as claimed in claim 2, wherein each of the FFs is positive edge trigger.

4. The auxiliary device as claimed in claim 2, wherein each of the FFs is a D-FF.

5. The auxiliary device as claimed in claim 1, wherein the delay circuit is a D-FF.

6. The auxiliary device as claimed in claim 1, wherein the second logic circuit is a logical OR gate.
